(19) United States
(12) Patent Application Publication
(10) Pub. No.: US 2017/0315152 A1
(43) Pub. Date: Nov. 2, 2017

(54) STACK TYPE TEST INTERFACE BOARD ASSEMBLY AND METHOD FOR MANUFACTURING THE SAME

(71) Applicant: CHUNGHWA PRECISION TEST TECH. CO., LTD., Taoyuan City (TW)

(72) Inventors: Cheng-Juei LIN, Taoyuan City (TW); Wen Tsung LI, Taoyuan City (TW); Yuan - Chiang TENG, Taoyuan City (TW); Kai Chieh HSIEH, Taoyuan City (TW)

(21) Appl. No.: 15/393,327

(22) Filed: Dec. 29, 2016

(30) Foreign Application Priority Data
Apr. 29, 2016 (TW) 105113515
Apr. 29, 2016 (TW) 105206205

(51) Int. Cl. G01R 1/073; H01L 21/48; G01R 1/04

(52) U.S. Cl. CPC G01R 1/07378; H01L 21/486; G01R 1/0491; H01L 21/4853; H01L 21/4857

(57) ABSTRACT

A stack type test interface board assembly is provided herein, which comprises: a space transform board having a narrow pitch transform board and a wide pitch transform board, a plurality of first connection nodes disposed on a side of the narrow pitch transform board to be electrically connected to a finished or semi-finished semiconductor product, a plurality of second connection nodes disposed on a side of the wide pitch transform board, and a printed circuit board where a side thereof is electrically connected to the plurality of the second connection nodes. The narrow pitch transform board and the wide pitch transform board are assembled in perpendicular stack into the space transform board. A pitch between each two of the plurality of the first connection nodes is smaller than a pitch between each two of the plurality of the second connection nodes.

### FIELD OF THE INVENTION

The present invention relates to a test interface board assembly and a method for manufacturing the same, and in particular to a stack type test interface board assembly and a method for manufacturing the same.

### BACKGROUND OF THE INVENTION

Please refer to FIGS. 1A and 1B. FIG. 1A illustrates a lateral-side diagram of a conventional test interface board assembly, which is generally adopted for a yield test of a semi-finished semiconductor product without being packaged, such as wafer 4. Such a test interface board assembly has a transform interface of different spaces (pitches) between the wafer and the test machine. For example, the main composition structure of the test interface board assembly includes an integrally-formed space transform (ST) board 1 having a space (pitch) between each two connecting nodes corresponding to I/O bumps of the tested wafer 4 in a narrower space specification, and a printed circuit board (PCB) 3 such as probe test loadboard having a space between each two of connecting nodes corresponding to probe connection nodes of the test machine in a wider space specification. The space transform board 1 and the printed circuit board 3 are welded together with solder balls 8 in ball grid array (BGA) therebetween in a proper space. The space transform board 1 further including ST metal pads 7 and PCB metal weld pads 6 is used for effectively connecting the signals of the tested wafer 4 with the test machine. FIG. 1B shows a lateral-view diagram of another conventional test interface board assembly, which is adopted for a yield test of a finished semiconductor product with being packaged, and includes a multilayer loadboard 5, solder balls 8, and probe 2.

However, limited to the process capability, the deployments of power and GND reduced greatly, the quality of power integration (PI) gets worse. Additionally, the deployments of the fan-out wirings are concentrated in 1-2 layers of the test loadboard structure, increasing the mutual interference of the signals between the wirings.

Therefore, it is necessary to provide a test interface board assembly and a method of manufacturing the same to increase the electrical quality, and reduce problem of the mutual interference of the signals.

### SUMMARY OF THE INVENTION

To solve the problem of prior art aforementioned, a purpose of the present invention is to provide a stack type test interface board assembly, the test interface board assembly is manufactured by divided board to shorten the manufacture time, the number of layers is decreased, and the yield is increased. The interference of signals is decreased by dividing the stages, and thus the width of wiring can be increased, the problem of unstable characteristic impedance is solved, and the transmission quality is increased.

A stack type test interface board assembly is provided according to an embodiment of the present invention, including: a space transform board and a printed circuit board, the space transform board including a narrow pitch transform board and a wide pitch transform board. A plurality of first connection nodes are disposed on a side of the narrow pitch transform board to be electrically connected to a finished or semi-finished semiconductor product, and a plurality of second connection nodes are disposed on a side of the wide pitch transform board; and a printed circuit board. A side of the printed circuit board is electrically connected to the plurality of the second connection nodes. The narrow pitch transform board and the wide pitch transform board are assembled in perpendicular stack into the space transform board, and a pitch between each two of the plurality of the first connection nodes is smaller than a pitch between each two of the plurality of the second connection nodes, a plurality of third connection nodes are disposed on the other side of the narrow pitch transform board, and the plurality of the third connection nodes are used for being electrically connected to the plurality of second connection nodes, through electrically connecting to the other side of the wide pitch transform board.

According to the embodiment of the present invention, each of the third connection nodes is a metal bump and welded to a corresponding weld pad on the other side of the wide pitch transform board, for establishing the electrical connection.

According to the embodiment of the present invention, each of the second connection nodes is a metal bump and welded to a corresponding weld pad on the side of the printed circuit board, for establishing the electrical connection.

According to the embodiment of the present invention, the printed circuit board is a probe card board used for testing the semi-finished semiconductor product, and the other side of the probe card board is used for being electrically connected to a test machine.

According to the embodiment of the present invention, the printed circuit board is a test loadboard used for testing the finished semiconductor product, and the other side of the test loadboard is used for being electrically connected to a test machine.

According to the embodiment of the present invention, at least one side hole is respectively formed on each of edges of the probe card board and the space transform board, for a fixing screw passing therethrough to fix with a nut.

According to the embodiment of the present invention, at least one side hole is respectively formed on each of edges of the test loadboard and the space transform board, for a fixing screw passing therethrough to fix with a nut.

According to the embodiment of the present invention, each metal bump is a copper bump.

According to the embodiment of the present invention, the plurality of the first connection nodes of the narrow pitch transform board are fan-in deployments, and a through hole or a blind hole is formed on the at least one of the first connection nodes.

According to the embodiment of the present invention, the plurality of the second connection nodes of the wide pitch transform board are fan-out deployments, and a through hole or a blind hole is formed on the at least one of the second connection nodes.

An embodiment of the present invention discloses a method for manufacturing a stack type test interface board assembly, including the following steps: separately manufacturing a narrow pitch transform board and a wide pitch transform board independently from each other. A plurality of first connection nodes are disposed on a side of the narrow pitch transform board to be electrically connected to a finished or semi-finished semiconductor product, a plurality of second connection nodes are disposed on a side of the wide pitch transform board, and a pitch between each two of the plurality of the first connection nodes is smaller than a pitch between each two of the plurality of the second connection nodes. The narrow pitch transform board and the wide pitch transform board are assembled in perpendicular stack into the space transform board. A plurality of third connection nodes are disposed on the other side of the narrow pitch transform board, the plurality of the third connection nodes are used for being electrically connected to the other side of the wide pitch transform board, and further electrically connecting the plurality of second connection nodes respectively. Assembling the space transform board and a printed circuit hoard, with electrically connecting a side of the printed circuit board to the plurality of second connection nodes of the wide pitch transform hoard.

The stack type test interface board assembly of the present invention is manufactured by divided board, wherein through hole or blind hole is respectively used on the wide pitch transform board and narrow pitch transform board, to achieve the design of the divided stages of fan-out and fan-in, and shorten the time spent for manufacturing the space transform board, and thus reduce the number of layers, increase the yield and dependence, and improve the test of wirings with smaller width and smaller space, decrease the difficulty of repair, and improve the transmission efficiency.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A illustrates a lateral-view diagram of a conventional test interface board assembly;

FIG. 1B illustrates a lateral-view diagram of another conventional test interface board assembly;

FIG. 2 illustrates a lateral-view diagram of the narrow pitch transform board according to a first embodiment of the present invention;

FIG. 3A illustrates a lateral-view diagram of the wide pitch transform board with a two-layers structure, according to the first embodiment of the present invention;

FIG. 3B illustrates a lateral-view diagram of the wide pitch transform board with a multi-layers structure, according to a second embodiment of the present invention;

FIG. 4 illustrates a lateral-view diagram of the assembled space transform board according to the first embodiment of the present invention;

FIG. 5 illustrates a lateral-view diagram of the assembled stack type test interface board assembly used for a semi-finished semiconductor product without packaged, according to the first embodiment of the present invention;

FIG. 6 illustrates a lateral-view diagram of the assembled stack type test interface board assembly used for the finished and packaged semiconductor product, according to the first embodiment of the present invention; and

FIG. 7 illustrates a flowchart of the method for manufacturing a stack type test interface board assembly according to an embodiment of the present invention.

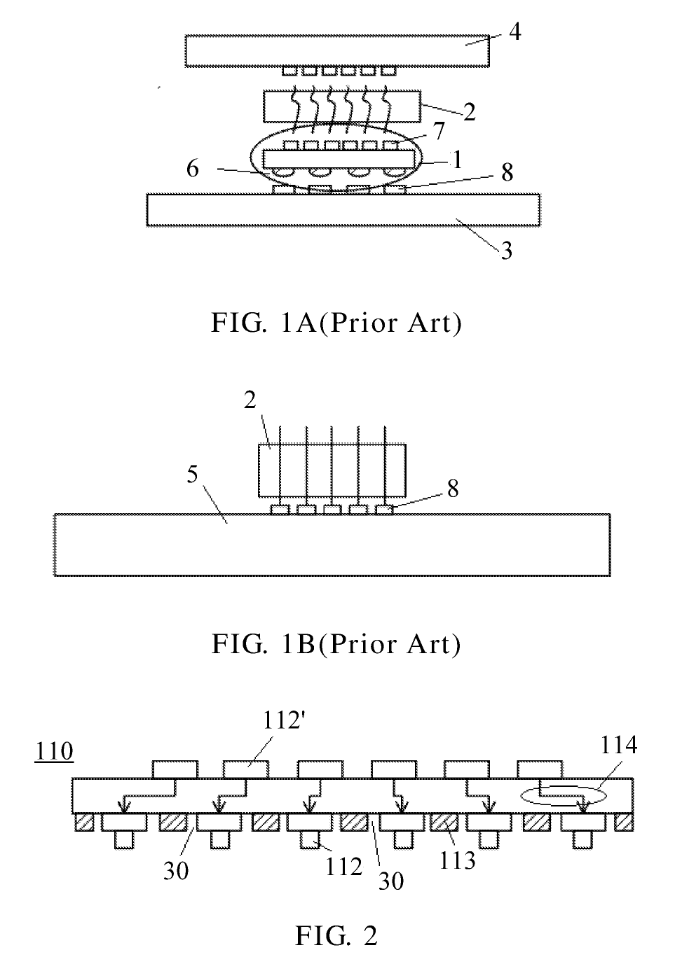

### DETAILED DESCRIPTION OF THE PREFERRED EMBODIMENTS

As used in this specification the term “embodiment” means an instance, example, or illustration. In addition, for the articles in this specification and the appended claims, “a” or “an” in general can be interpreted as “one or more” unless specified otherwise or clear from context to determine the singular form.

In the drawings, the same reference numerals denote units with similar structures.

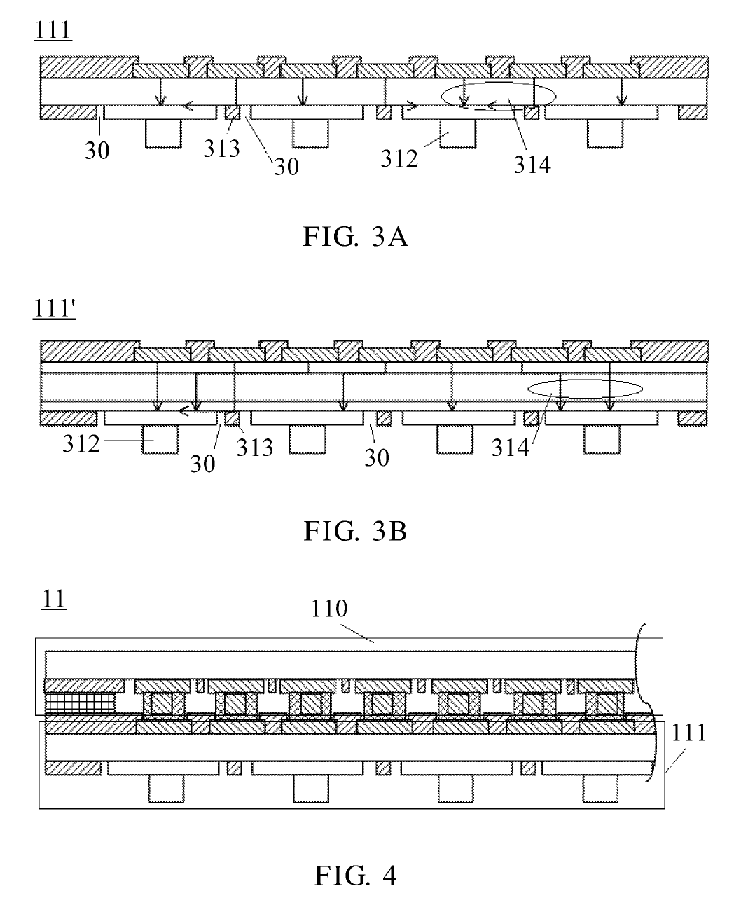

Please refer to FIG. 2 and FIG. 3A. FIG. 2 illustrates a lateral-view diagram of the narrow pitch transform board according to a first embodiment of the present invention. FIG. 3A illustrates a lateral-view diagram of the wide pitch transform board with a two-layers structure, according to the first embodiment of the present invention. The stack type test interface board assembly of the present invention mainly includes a printed circuit board 10 and a space transform (ST) board 11. The space transform board 11 includes a narrow pitch transform board 110 and a wide pitch transform board 111 both which are manufactured and formed independently from each other. The narrow pitch transform board 110 has a plurality of first connection nodes 112 disposed on a side thereof so as to be electrically connected to a finished semiconductor product such as chip, or a semi-finished semiconductor product such as wafer. The wide pitch transform board 111 has a plurality of second connection nodes 312 disposed on a side thereof. In this embodiment, the narrow pitch transform board 110 and the wide pitch transform board 111 are assembled in perpendicular stack into the space transform board 11. A pitch between each two of the plurality of the first connection nodes 112 is smaller than a pitch between each two of the plurality of the second connection nodes 312. The narrow pitch transform board 110 has a plurality of third connection nodes 112′ disposed on the other side thereof and used for being electrically connected to the plurality of second connection nodes 312, through electrically connecting to the other side of the wide pitch transform board 111.

Preferably, each of the third connection nodes 112′ is a metal bump and welded to a corresponding weld pad on the other side of the wide pitch transform board 111, for establishing the electrical connection. There is a compartment layer 113 formed between every two adjacent metal bumps. As marked in FIG. 2, an arrow indicates a transmission path 114 of each metal bump in the narrow pitch transform board 110.

FIG. 3B shows a lateral-view diagram of the wide pitch transform board with a multi-layers structure, according to a second embodiment of the present invention.

Preferably, each second connection node 312 is a metal bump. There is a compartment layer 313 formed between every two adjacent metal bumps, and as marked in FIGS. 3A and 3B, the arrow indicates a transmission path 314 of each metal bump in the wide pitch transform board 111.

Preferably, each aforementioned metal bump is a copper hump.

Please refer to FIG. 4 which illustrates a lateral-view diagram of an assembled space transform board according to the first embodiment of the present invention. The space transform board 11 includes a narrow pitch transform board 110 and a wide pitch transform board 111, wherein a pad material 40 and solder paste 41 are intermediately disposed therebetween.

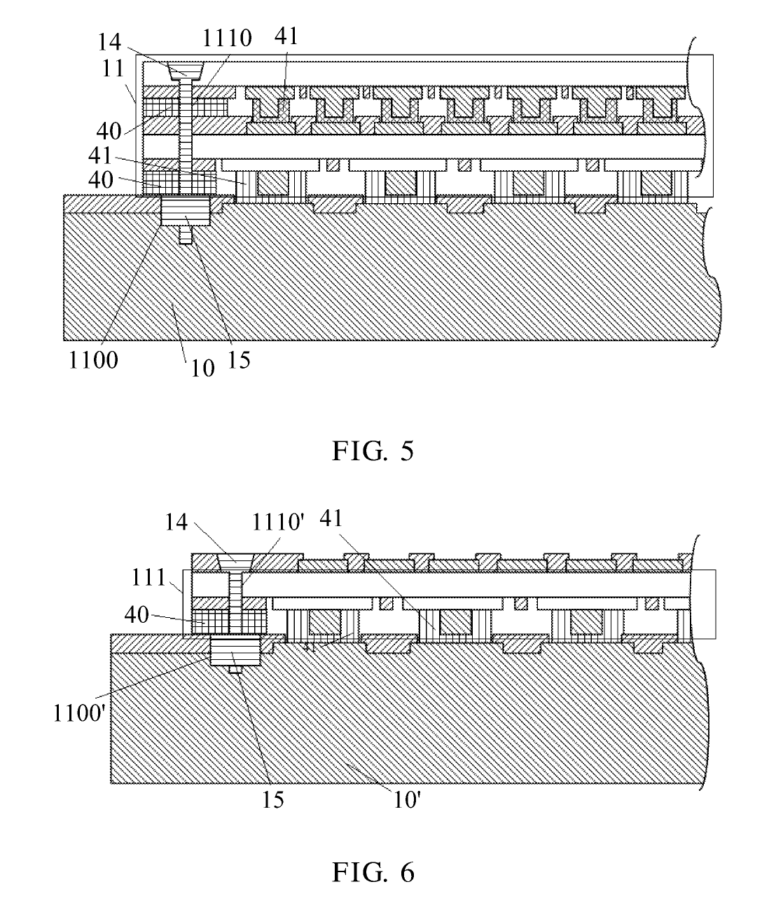

Please refer to FIG. 5 which illustrates a lateral-view diagram of assembled the stack type test interface board assembly, applied for a semi-finished semiconductor product which has not been packaged yet, according to the first embodiment of the present invention. Each of the second connection nodes 312 is welded to the weld pad on the side of the printed circuit board 10 to form an electrical connection therebetween. The printed circuit board 10 is realized as a probe card board, used for testing the semi-finished semiconductor product, and the other side of the probe card board 10 is used for electrically connecting to a test machine.

Preferably, at least one side holes 1100, 1110 are respectively formed on each of edges of the printed circuit board 10 and the space transform board 11, for a fixing screw 14 passing therethrough to fix with a nut 15.

Please refer to FIG. 6 which illustrates a lateral-view diagram of the assembled stack type test interface board assembly, applied for a finished semiconductor product which has been packaged, according to the first embodiment of the present invention. Each of the second connection nodes 312 is welded to the weld pad on the side of the printed circuit board 10′ to form an electrical connection therebetween. The printed circuit board 10′ is realized as a test loadboard (Loadboard PCB), used for testing the finished semiconductor product, and the other side of the printed circuit board 10′ is used for electrically connecting to a test machine.

Preferably, at least one side hole 1100′, 1110′ are respectively formed on each of edges of the probe card board 10′ and the space transform board 11, for a fixing screw 14 passing therethrough to fix with a nut 15.

Preferably, the plurality of the first connection nodes 112 of the narrow pitch transform board 110 are fan-in deployments, and a through hole or a blind hole 30 is formed at the at least one of the first connection nodes 112.

Preferably, the plurality of the second connection nodes 312 of the wide pitch transform board 111 are fan-out deployments, and a through hole or a blind hole 30 is formed at the at least one of the second connection nodes 312.

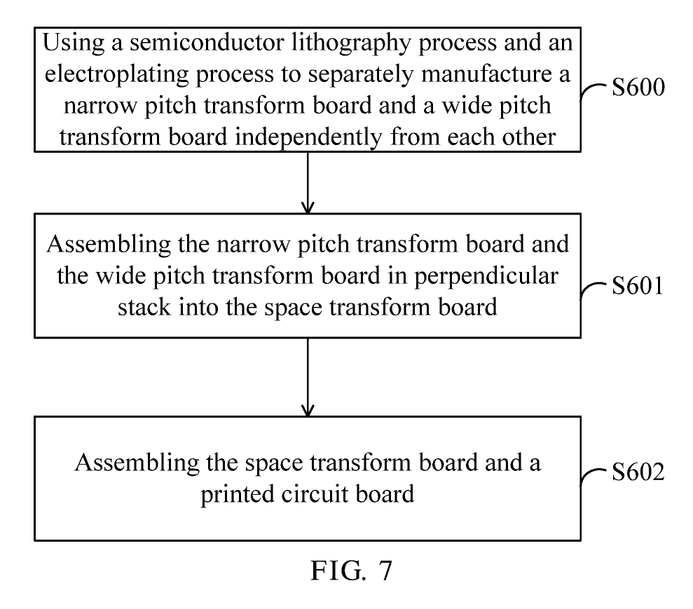

Please refer to FIG. 7 which illustrates a flowchart of a method for manufacturing a stack type test interface board assembly, according to an embodiment of the present invention. The method can be applied for manufacturing the stack type test interface board assembly shown in FIG. 5 or FIG. 6, includes the following steps of:

S600: using a semiconductor lithography process and an electroplating process to separately manufacture a narrow pitch transform board and a wide pitch transform board independently from each other, wherein the detail structures of the narrow pitch transform board and the wide pitch transform board are the same as the structures shown in FIG. 5 or FIG. 6, thus there is no more description in the following steps. “manufactured separately and independently” herein means separate and independent manufacture at the same time or at different time;

S601: assembling the narrow pitch transform board and the wide pitch. transform board in perpendicular stack into the space transform board, through the plurality of metal bumps between the narrow pitch transform board and the wide pitch transform board; and

S602: assembling the space transform board and a printed circuit board (as the probe card board shown in FIG. 5 or the test loadboard shown in FIG. 6) through fixing screw and fixing nut, and electrically connecting the space transform board and the printed circuit board.

The stack type test interface board assembly of the present invention is manufactured by divided board to shorten the time spent for manufacturing the space transform board, and thus reduce the number of layers, increase the yield and dependence, and improve the test of wirings with smaller width, decrease the difficulty of repair, and improve the transmission efficiency.

In summary, although the preferable embodiments of the present invention have been disclosed above, the embodiments are not intended to limit the present invention. A person of ordinary skill in the art, without departing from the spirit and scope of the present invention, can make various modifications and variations. Therefore, the scope of the invention is defined in the claims.

What is claimed is:

1. A stack type test interface board assembly, comprising:
a space transform board, including a narrow pitch transform board and a wide pitch transform board, wherein a plurality of first connection nodes are disposed on a side of the narrow pitch transform board to be electrically connected to a finished or semi-finished semiconductor product, and a plurality of second connection nodes are disposed on a side of the wide pitch transform board; and
a printed circuit board where a side thereof is electrically connected to the plurality of the second connection nodes;
wherein the narrow pitch transform board and the wide pitch transform board are assembled in perpendicular stack into the space transform board, and a pitch between each two of the plurality of the first connection nodes is smaller than a pitch between each two of the plurality of the second connection nodes, a plurality of third connection nodes are disposed on the other side of the narrow pitch transform board, and the plurality of the third connection nodes are used for electrically connecting to the plurality of second connection nodes, through electrically connecting to the other side of the wide pitch transform board.

2. The stack type test interface board assembly of claim 1, wherein each of the third connection nodes is a metal bump and welded to a corresponding weld pad on the other side of the wide pitch transform board, for establishing the electrical connection.

3. The stack type test interface board assembly of claim 1, wherein each of the second connection nodes is a metal bump and welded to a corresponding weld pad on the side of the printed circuit board, for establishing the electrical connection.

4. The stack type test interface board assembly of claim 1, wherein the printed circuit board is a probe card board used for testing the semi-finished semiconductor product, and the other side of the probe card board is used for being electrically connected to a test machine.

5. The stack type test interface board assembly of claim 1, wherein the printed circuit board is a test loadboard used for testing the finished semiconductor product, and the other side of the test loadboard is used for being electrically connected to a test machine.

6. The stack type test interface board assembly of claim 4, wherein at least one side hole is respectively formed on each of edges of the probe card board and the space transform board, for a fixing screw passing therethrough to fix with a nut.

7. The stack type test interface board assembly of claim 5, wherein at least one side hole is respectively formed on each of edges of the test loadboard and the space transform board, for a fixing screw passing therethrough to fix with a nut.

8. The stack type test interface board assembly of claim 2, wherein each metal bump is a copper bump.

9. The stack type test interface board assembly of claim 3, wherein each metal hump is a copper bump.

10. The stack type test interface board assembly of claim 1, wherein the plurality of the first connection nodes of the narrow pitch transform board are fan-in deployments, and a through hole or a blind hole is formed on the at least one of the first connection nodes.

11. The stack type test interface board assembly of claim 1, wherein the plurality of the second connection nodes of the wide pitch transform board are fan-out deployments, and a through hole or a blind hole is formed on the at least one of the second connection nodes.

12. A method for manufacturing a stack type test interface board assembly, comprising the following steps of:
separately manufacturing a narrow pitch transform board and a wide pitch. transform board independently from each other, wherein a plurality of first connection nodes are disposed on a side of the narrow pitch transform board to be electrically connected to a finished or semi-finished semiconductor product, a plurality of second connection nodes are disposed on a side of the wide pitch transform board, and a pitch between each two of the plurality of the first connection nodes is smaller than a pitch between each two of the plurality of the second connection nodes;
assembling the narrow pitch transform board and the wide pitch transform board in perpendicular stack into the space transform board, wherein a plurality of third connection nodes are disposed on the other side of the narrow pitch transform board, the plurality of the third connection nodes are used for being electrically connected to the other side of the wide pitch transform board, and further electrically connecting the plurality of second connection nodes respectively; and
assembling the space transform board and a printed circuit board, with electrically connecting a side of the printed circuit board to the plurality of second connection nodes of the wide pitch transform board.
